(19) United States
(12) Patent Application Publication
(10) Pub. No.: US 2026/0314421 A1
(43) Pub. Date: Oct. 8, 2026

(54) DEEP TRENCH ISOLATION FOR SEMICONDUCTOR DEVICES WITH ENHANCED BREAKDOWN PROTECTION

(71) Applicant: Taiwan Semiconductor Manufacturing Company, LTD., Hsinchu (TW)

(72) Inventor: Yen Chang Tseng, Hsinchu (TW)

(21) Appl. No.: 19/172,792

(22) Filed: Apr. 8, 2025

(51) Int. Cl. H01L 23/00; H01L 21/265; H01L 21/762; H01L 23/528

(52) U.S. Cl. CPC H10W 42/121; H10P 30/204; H10P 30/208; H10W 10/014; H10W 10/17; H10W 20/43

(57) ABSTRACT

At least one electronic device is encircled by an inner deep trench isolation (DTI) ring and an outer DTI ring encircling the inner DTI ring. A semiconductor structure includes at least one electronic device surrounded by at least one DTI ring, where each DTI ring has a circular layout, an oval layout, or a polygonal layout with at least five sides. A method of fabricating a semiconductor structure includes etching at least one trench ring into a semiconductor layer or substrate with sidewalls that are not perpendicular respective to a surface of the semiconductor layer or substrate, performing ion implantation into the sidewalls and bottom of the at least one trench ring, filling the at least one trench ring with a filler material to form a corresponding at least one DTI ring, and forming at least one electronic device inside the at least one DTI ring.

### BACKGROUND

The following relates to the semiconductor fabrication arts, integrated circuit (IC) arts, Bipolar-CMOS-DMOS (BCD) fabrication arts, electromagnetic interference (EMI) protection arts, deep trench isolation (DTI) arts, and related arts.

High voltage electronic devices of an IC or other semiconductor circuitry fabricated on a semiconductor wafer can generate EMI that can interfere with other electronic devices fabricated on the semiconductor wafer. As a nonlimiting illustrative example, the high voltage electronic device(s) may be fabricated in BCD technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a top (i.e., plan) view of electronic structure fabricated on a semiconductor layer or substrate.

FIG. 2 diagrammatically illustrates Cut C-C indicated in FIG. 1.

FIG. 3 shows a flowchart for fabricating the electronic structure of FIGS. 1 and 2.

FIGS. 4A, 4B, 4C, 4D, 4E, and 4F show views taken along Cut C-C indicated in FIG. 1 after corresponding fabrication steps of the flowchart of FIG. 3.

FIGS. 5, 6, 7, and 8 diagrammatically illustrates top (i.e., plan) views of electronic structures fabricated on a semiconductor layer or substrate in some variant embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Electromagnetic interference (EMI) protection for a high voltage electronic device or group of devices can be implemented with deep trench isolation (DTI) with a rectangular layout formed in the periphery of the active area and enclosing the high voltage electronic device(s). The DTI provides good EMI isolation-however, the DTI can be a weak point for breakdown when operating the device(s) at high voltage. In embodiments disclosed herein, improved DTI for EMI isolation is disclosed, which enhances the breakdown voltage of the DTI, thus enabling EMI isolation of high voltage electronic devices without reducing the breakdown voltage (or, at least, with less reduction in the breakdown voltage) due to the DTI.

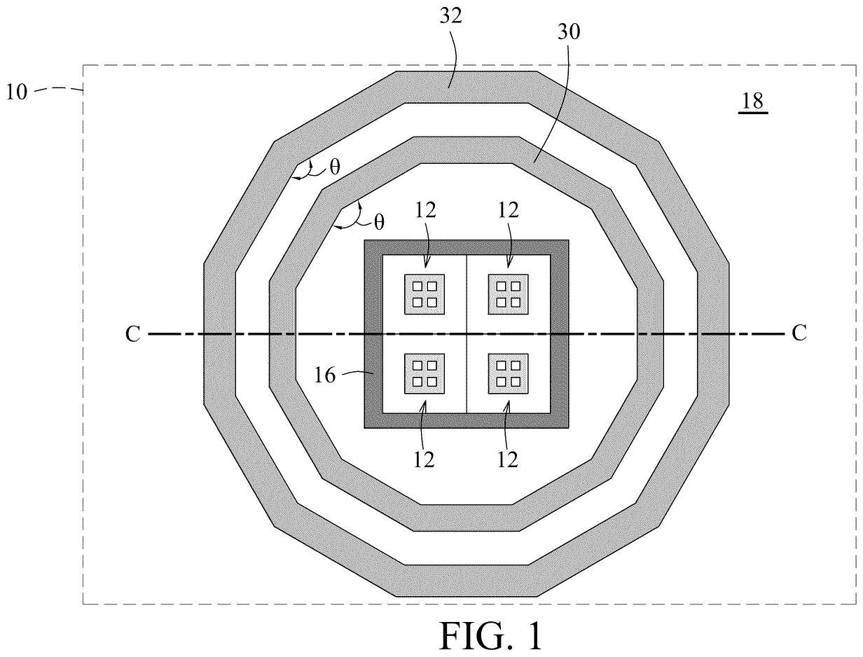

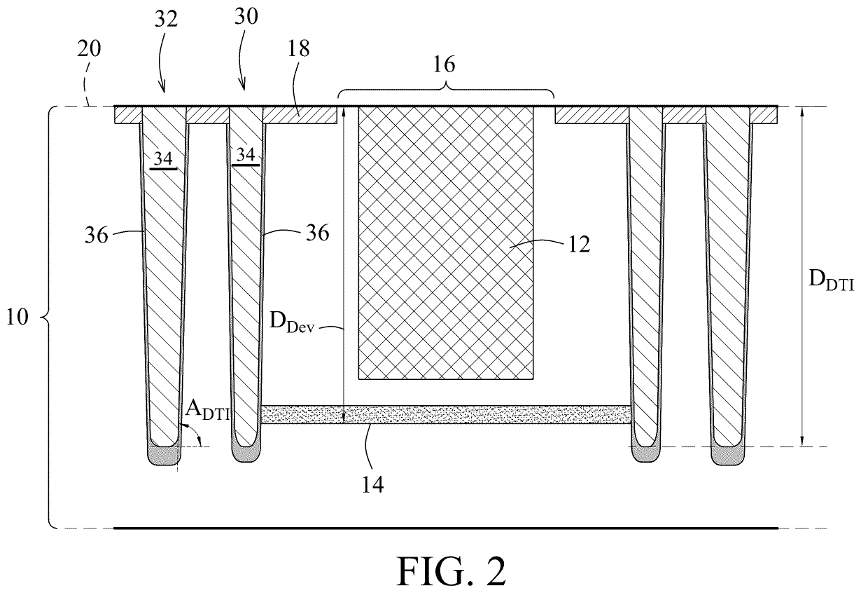

With reference to FIGS. 1 and 2, a top (i.e., plan) view (FIG. 1) and a Cut C-C (FIG. 2) are diagrammatically shown of a semiconductor structure formed on and/or in a semiconductor layer or substrate 10. The semiconductor structure comprises one or more (illustrative four) electronic devices 12 fabricated on and/or in the semiconductor layer or substrate 10. The semiconductor layer or substrate 10 may be a silicon wafer, a silicon-on-insulator (SOI) wafer, a semiconductor layer or substrate comprising a different type of semiconductor (e.g., silicon-germanium alloy, gallium arsenide wafer, et cetera), or so forth. The one or more electronic devices 12 may, for example, include bipolar-CMOS-DMOS (BCD) devices, where CMOS stands for complementary metal-oxide-semiconductor and DMOS stands for double-diffused MOS or a variant thereof (e.g., LDMOS or lateral double-diffused MOS). Such devices can support operation at high voltages (e.g., tens or hundreds of volts) and at high frequency (e.g., radio frequencies, or RF), with small device critical dimensions, e.g., of tens of nanometers or less. By way of nonlimiting illustrative example, such BCD devices 12 may be employed in power amplifiers for automotive, audio, and/or other applications.

As diagrammatically indicated in FIG. 2, the BCD or other electronic device(s) 12 are fabricated in the semiconductor layer or substrate 10 to a depth D_{Dev}, where may D_{Dev} may in some nonlimiting illustrative examples be about 18-22 microns (where the device depth D_{Dev} is considered to include a buried doped layer 14 such as an N-type buried layer (NBL) formed by ion implantation). More particularly, the one or more electronic device(s) 12 are formed in a device area 16 of the semiconductor layer or substrate 10. The device area 16 is also (or alternatively) sometimes referred to as an active area or an OD area or similar nomenclature. Shallow trench isolation (STI) 18 surrounds the device area 16. As seen in FIG. 2, the STI 18 comprises an oxide (e.g., silicon oxide or SiO₂, although another type of oxide such as silicon oxynitride or silicon nitride is contemplated) formed in (i.e., penetrating shallowly into) a surface 20 of the semiconductor layer or substrate 10. Optionally, the device area 16 may be delineated by a field oxide or a gate oxide formed on the surface 20 (and/or in the surface 20, e.g., in the case of a thermal oxide formed on silicon), a doped region formed by dopant implantation or dopant diffusion, and/or other layer and/or layers and/or structure(s) (not shown) deposited and/or formed on and/or in the surface 20 of the semiconductor layer or substrate 10 within the device area 16.

With continuing reference to FIGS. 1 and 2, as the electronic devices 12 may operate at high voltage and high frequency (e.g., audio or RF frequencies for some BCD devices), there is substantial potential for generating electromagnetic interference (EMI). To provide EMI protection, the semiconductor structure further includes at least one deep trench isolation (DTI) ring 30, 32 encircling the device area 16. In the illustrative example, the at least one DTI ring 30, 32 includes an inner DTI ring 30 encircling the at least one electronic device 12 and the device area 16, and an outer DTI ring 32 encircling the inner DTI ring 30. In some embodiments, the DTI ring or rings may have a rectangular layout. However, the illustrative inner and outer DTI rings 30 and 32 of the semiconductor structure of FIGS. 1 and 2 has a polygonal layout with twelve sides. More generally, in some embodiments each DTI ring 30, 32 has a polygonal layout with at least five sides. An advantage of increasing the number of sides of a polygonal layout of the DTI ring is that the angle between adjacent sides decreases with increasing number of sides. For a DTI ring with N sides, the angle between two adjacent sides is 360°/N. Hence, for a four-sided DTI ring the largest angle is 90°, whereas for a five-sided DTI ring the largest angle is 72°. For the illustrative DTI rings 30 and 32 with N=12 sides, the largest angle θ is 30°. This approach of having the number of sides of the polygonal layout of the DTI ring be at least five (i.e., N≥5) and in some embodiments having N>5, N≥8, or an even larger value of N (e.g., illustrative N=12) advantageously reduces structural stress at the corners between adjacent sides of the DTI ring with polygonal layout. More generally, the DTI ring may be designed to have the largest angle between any two adjacent sides be less than 90^{o} to reduce the structure stress at the corners. The reduced structural stress, in turn, reduces likelihood of a voltage breakdown initiating at a corner between adjacent sides of the DTI ring, thereby advantageously increasing the breakdown voltage (BV) of the semiconductor structure including the DTI ring(s) 30, 32 when the semiconductor device(s) 12 are biased at high voltage (e.g., tens of volts or higher in some nonlimiting illustrative example biases).

In some embodiments, the DTI ring or rings may have a number of sides N which is greater than or equal to five, and that is also chosen to align the sides of the DTI ring(s) with crystalline planes of the crystalline semiconductor layer or substrate 10. For example, if the semiconductor layer or substrate 10 is crystalline silicon or GaAs with a cubic crystalline structure, N=6 or N=8 (depending on the crystalline orientation of the surface 20, e.g., whether it is a <111> surface, a <001> surface, or so forth) may be advantageous for aligning the sides of the DTI ring(s) with crystalline planes of the crystalline silicon layer or substrate 10.

In some embodiments, the DTI ring or rings may have an oval or circular layout. This conceptually corresponds to a polygonal layout with the number of sides N approaching infinity, i.e., N→∞). In this case, the DTI ring with oval or circular layout has no corners that could serve as initiation points for voltage breakdown.

With particular reference to the cut C-C view of FIG. 2, each DTI ring 30 and 32 includes a filler material 34. In some nonlimiting illustrative embodiments in which the material of the semiconductor layer or substrate 10 is crystalline silicon (e.g., a single-crystal silicon wafer or an SOI wafer with a crystalline silicon layer), the filler material 34 comprises polycrystalline silicon (polysilicon). However, other types of filler material are contemplated. In general, the filler material 34 is a different material than the material of the semiconductor layer or substrate 10, and/or the filler material 34 has a different microstructure than the material of the semiconductor layer or substrate 10 (e.g., the filler material 34 is polycrystalline silicon while the semiconductor layer or substrate 10 is crystalline silicon, in some illustrative examples). By having the filler material 34 be a different material and/or have different microstructure than the material of the semiconductor layer or substrate 10, the DTI rings 30 and 32 presents a barrier to propagation of electromagnetic signals passing through the DTI rings, so as to advantageously provide EMI protection for the electronic device(s) 12 disposed inside the DTI ring(s) 30, 32, and/or to protect electronics located outside of the DTI ring(s) 30, 32 (for example, elsewhere on the semiconductor layer or substrate 10) from EMI generated by the electronic device(s) 12 disposed inside the DTI ring(s)) 30, 32.

As further diagrammatically shown in FIG. 2, each DTI ring 30 and 32 includes an optional channel stop implant 36 surrounding the filler material 34. Viewed another way, the optional channel stop implant 36 surrounds the sidewall and bottom of the DTI 30 and 32). The optional channel stop implant 36, if included, ensures that a conductive channel is not inadvertently formed at the interface between the filler material 34 and the surrounding material of the semiconductor layer or substrate 10. As a nonlimiting illustrative example, if the material of the semiconductor layer or substrate 10 is P-type then the channel stop implant 36 may be P-type at a higher peak doping concentration than the P-type doping of the semiconductor layer or substrate 10.

As seen in both the top view of FIG. 1 and the cut C-C of FIG. 2, the STI 18 is formed in a surrounding region that surrounds the device area 16, and the at least one DTI ring 30 and 32 is formed in the surrounding region. Thus, as seen in the illustrative example of FIG. 2, the inner DTI ring 30 passes through the STI 18, and the outer DTI ring 32 passes through the STI 18. Placement of the DTI ring(s) 30 and 32 in (a portion of) the same area as the STI 18 (as best seen in FIG. 1) advantageously facilitates a compact layout for the semiconductor structure, and also spaces the DTI ring(s) 30 and 32 further away from the electronic device(s) 12 than would be the case if the DTI rings were formed in the device area 16, thus (further) reducing the likelihood of a voltage breakdown initiating at the DTI ring(s) 30 or 32.

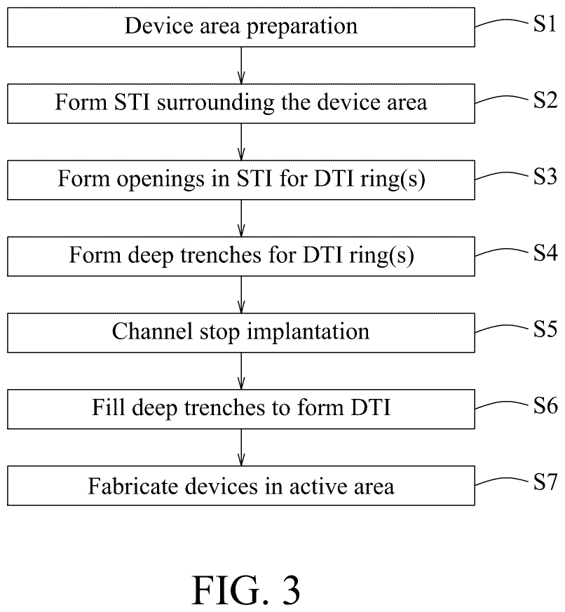

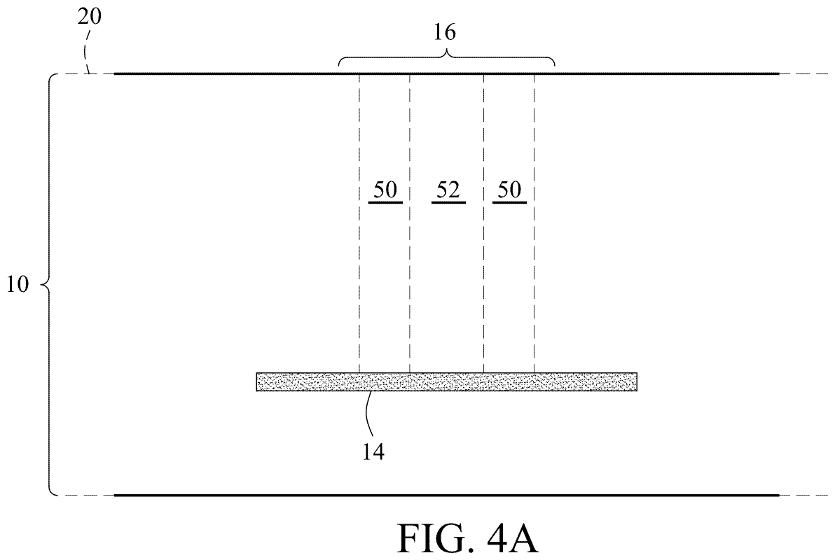

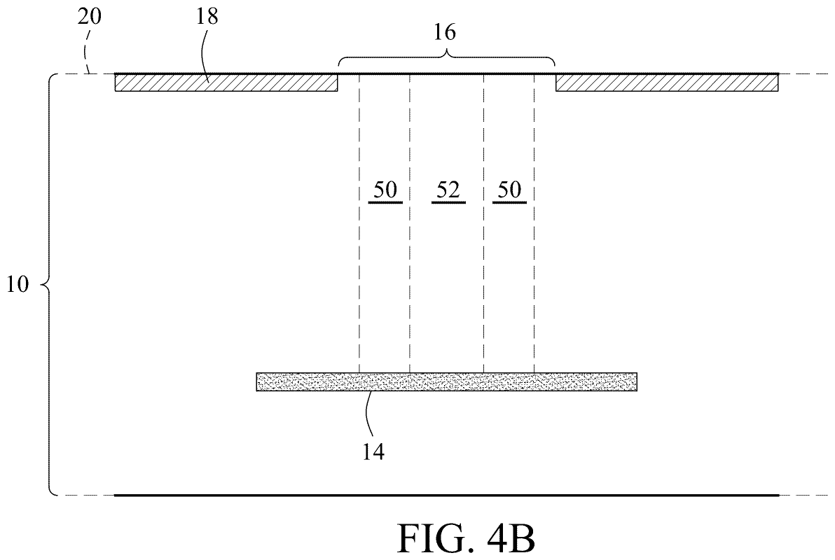

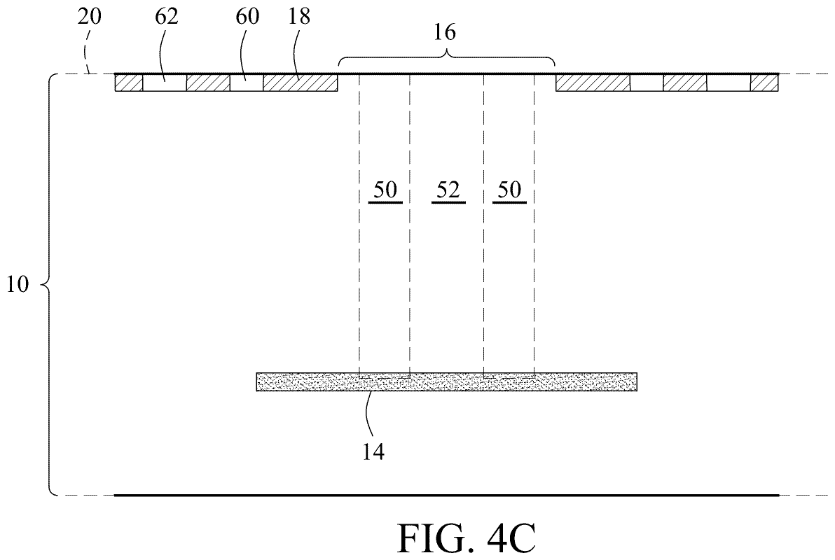

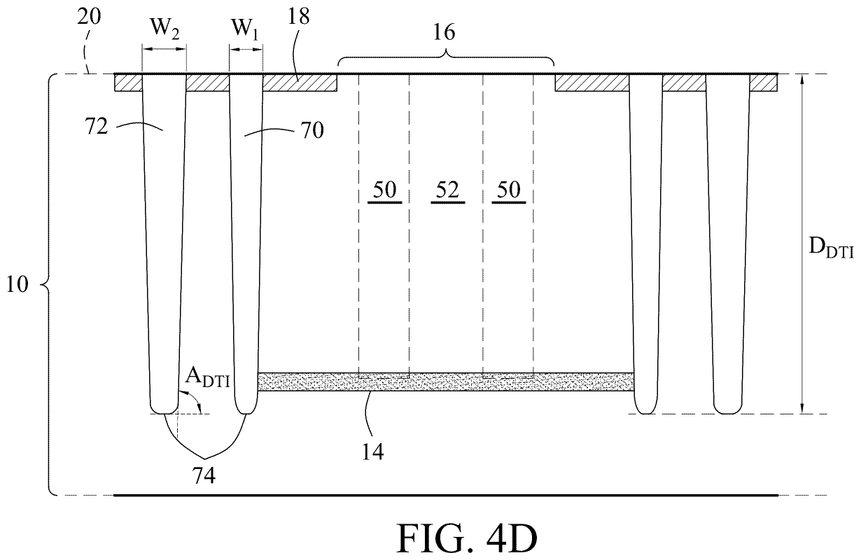

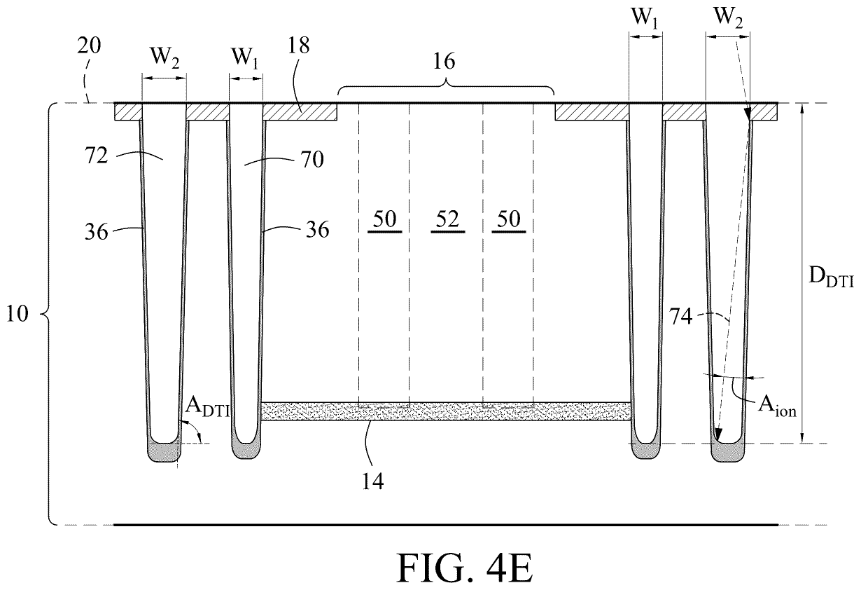

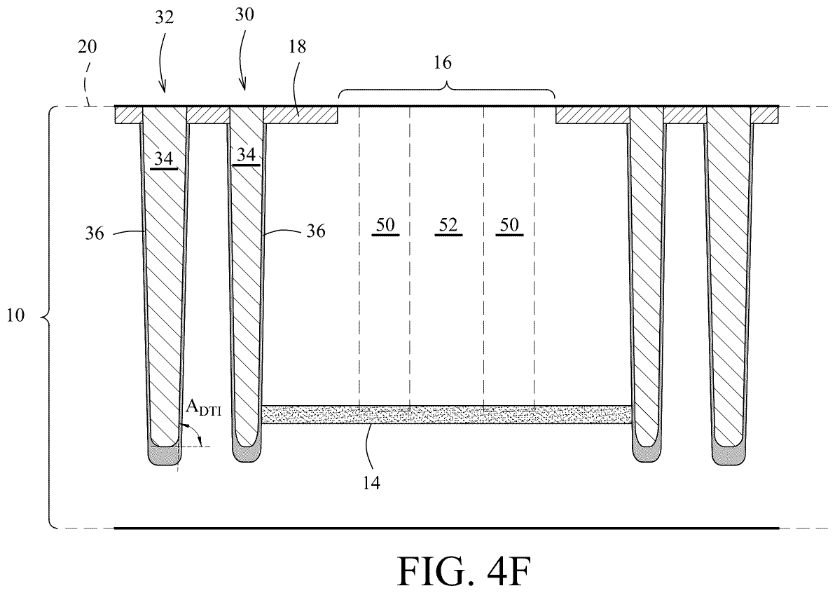

With reference now to FIG. 3 and successive reference to FIGS. 4A, 4B, 4C, 4D, 4E, and 4F, a nonlimiting illustrative method of fabricating the semiconductor structure of FIGS. 1 and 2 is described and illustrated by way of a flowchart (FIG. 3) and views taken along Cut C-C indicated in FIG. 1 after corresponding fabrication steps indicated in the flowchart of FIG. 3. In an initial optional step S1 indicated in FIG. 3 and shown by cut C-C in FIG. 4A, the device area 16 may be prepared. In the illustrative example of FIG. 4A, the optional device area preparation S1 include forming the buried doped layer 14 by ion implantation, and performing dopant implantations to form one or more N-type wells 50 and/or one or more P-type wells 52 destined to serve, for example, as HVNW and HVPW regions of the one or more electronic devices 12. In a nonlimiting illustrative example, if the semiconductor layer or substrate 10 is doped P-type then the buried doped layer 14 may be an N-type buried layer (NBL) formed by ion implantation. These are merely nonlimiting illustrative examples of some possible device area preparation operations and resulting structures, and more generally the optional device area preparation S1 may optionally include other operations (not shown) such as forming a field oxide and/or gate oxide on the surface 20 of the semiconductor layer or substrate 10 disposed over portion(s) or all of the device area 16.

With continuing reference to FIG. 3 and with further reference to FIG. 4B, in a step S2 the shallow trench isolation (STI) 18 is formed. This may, for example, entail forming a shallow trench by photolithographically patterned dry etching into the surface 20 of the semiconductor layer or substrate 10 and filling the trench with silicon dioxide (SiO₂) or another chosen oxide material.

With continuing reference to FIG. 3 and with further reference to FIG. 4C, in a step S3 openings 60 and 62 are formed in the STI 18, corresponding to the destined DTI rings 30 and 32, respectively. More particularly, an inner opening ring 60 is formed which corresponds to the destined inner DTI ring 30, and an outer opening 62 is formed which corresponds to the destined outer DTI ring 32. Although not visible in the cut C-C view of FIG. 4C, it will be appreciated that the inner opening 60 in the STI 18 has the same ring layout (and, more particularly, illustrative polygonal ring layout) as the destined inner DTI ring 30; and likewise, the outer opening 62 has the same ring layout (and, more particularly, illustrative polygonal ring layout) as the destined outer DTI ring 32. The openings 60 and 62 may, for example, be etched in the STI 18 using patterned wet or dry etching with an etchant that etches SiO₂ (if the STI 18 is made of SiO₂). For example, a suitable wet etchant is hydrofluoric acid (HF), while suitable etching gases for dry etching may include a fluoride-based gas such as CF₄, SF₆, NF₃, or so forth. If the chosen etchant does not etch silicon (or other material making up the semiconductor layer or substrate 10), then this etching has a built-in etch stop.

With continuing reference to FIG. 3 and with further reference to FIG. 4D, in a step S4 trenches 70, 72 are formed for the DTI rings 30, 32. More particularly, an inner trench 70 is formed through the ring-shaped opening 60 in the STI 18, which is destined to be filled with the filler material 34 to form the inner DTI ring 30; and an outer trench 72 is formed through the ring-shaped opening 62 in the STI 18, which is destined to be filled with the filler material 34 to form the outer DTI ring 32. The trenches 70 and 72 are deep trenches, insofar as they are substantially deeper than the STI 18. Although not visible in the cut C-C view of FIG. 4D, it will be appreciated that the inner deep trench 70 has the same ring layout (and, more particularly, illustrative polygonal ring layout) as the destined inner DTI ring 30; and likewise, the outer deep trench 72 has the same ring layout (and, more particularly, illustrative polygonal ring layout) as the destined outer DTI ring 32. The deep trench etching step S4 may, for example, entail dry etching the trenches 70 and 72 to the depth D_{DTI} of the destined DTI rings 30 and 32 using dry etching with an etchant that etches the silicon (if the semiconductor layer or substrate 10 comprises silicon) such as a chlorine-based etchant gas such as Cl₂, CCl₂F₂, or so forth. If the etchant is selective for silicon (or other material of the semiconductor layer or substrate 10) over the oxide material of the STI 18, then the STI 18 may optionally serve as a mask for the deep trench etching step S4. Alternatively (or if the etchant is not sufficiently selective) then photolithographically patterned dry etching may be employed.

As further shown in FIG. 4D, the deep etching step S4 may employ an etching recipe (controlled by parameters such as etchant flow rate, dry etching chamber pressure, RF power, and so forth) and patterned photoresist profile to form the deep trench rings 70 and 72 with slanted or angled sidewalls, which are angled at a non-perpendicular angle A_{DTI} as diagrammatically indicated in FIG. 4D. In some embodiments, the trench rings 70 and 72 are formed with sidewalls angled at between 85 degrees and 88 degrees (that is, 85 degrees≤A_{DTI}≤88 degrees. The angled sidewalls facilitate the subsequent step of performing ion implantation into the sidewalls. The non-perpendicular angle A_{DTI} is optional, and perpendicular sidewalls for the deep trenches is alternatively contemplated. The etching recipe is also optionally designed to etch the trench rings 70 and 72 with rounded bottoms 74.

The illustrative trench rings 70 and 72 have respective widths W₁ and W₂ as indicated in FIG. 4D. While the width W₂ of the outer deep trench 72 is shown as slightly larger than the width W₁ of the inner deep trench 70, it is alternatively contemplated for the outer and inner trenches to have equal widths (i.e., W₁=W₂) or for the outer deep trench ring to have a narrower width than the inner deep trench ring. In some embodiments, it is contemplated for a ratio of the deep trench depth D_{DTI} to the deep trench width W (e.g., W₁ or W₂) to be in a range of 15≤(D_{DTI}/W)≤18, although values outside of this range are also contemplated. As a nonlimiting illustrative example, if D_{DTI} is about 18-22 microns (which may be suitable for some BCD electronics technology platforms) and the critical dimension for the DTI rings 30 and 32 is about 1.2 microns, then the ration/D_{DTI}/W is_{DTI} in a range of about 15.0 to 18.3 microns.

With continuing reference to FIG. 3 and with further reference to FIG. 4E, in an optional step S5 a channel stop implantation is performed to form the optional channel stop implant 36. The channel stop implant S5 may be performed using an ion implantation tool, and dopant implantation into the sidewalls of the deep trenches 70 and 72 is facilitated by the slanted or angled sidewalls being angled at the non-perpendicular angle A_{DTI}. Implantation into the sidewalls is also facilitated by using ion implantation parameters that provide an angular distribution for the incident dopant ions. FIG. 4E shows a single nonlimiting illustrative ion path 74 having an angle Aᵢₒₙ which may, for example, be around 3 degrees as a nonlimiting example. Such an angular distribution of the ions, together with the slanted or angled sidewalls of the deep trenches 70 and 72, facilitates ion implantation along the entireties of the sidewalls and bottoms of the deep trenches 70 and 72. As previously mentioned, the optional channel stop implant 36, if included, ensures that a conductive channel is not inadvertently formed at the interface between the filler material 34 of the destined DTI rings 30 and 32 and the surrounding material of the semiconductor layer or substrate 10. As a nonlimiting illustrative example, if the material of the semiconductor layer or substrate 10 is P-type then the channel stop implant 36 may be P-type at a higher peak doping concentration than the P-type doping of the semiconductor layer or substrate 10. In one nonlimiting example, the step S5 may employ boron ions to provide P-type dopant implantation.

With continuing reference to FIG. 3 and with further reference to FIG. 4F, in a step S6 the inner and outer deep trench rings 70 and 72 are filled with the filler material 34 to form the respective inner and outer DTI rings 30 and 32. This can be done using a material deposition tool such as a chemical vapor deposition (CVD) tool to deposit the polycrystalline silicon (i.e., polysilicon) in an embodiment in which the semiconductor layer or substrate 10 is silicon. Photolithographic masking may be employed to limit the polysilicon deposition to the deep trench rings 70 and 72, and/or chemical mechanical polishing (CMP) may be employed to remove any excess polysilicon deposited on the surface 20 of the semiconductor layer or substrate 10.

With continuing reference to FIG. 3 and with further reference back to FIG. 2, in a step S7 the electronic devices 12 are fabricated on and/or in the device area 16 of the semiconductor layer or substrate 10. The device fabrication workflow depends on the type or types of electronic devices 12. In some embodiments, the device fabrication workflow may be viewed as including the previously performed optional device area preparation step S1 (e.g., previously described with reference to FIG. 4A, which in the illustrative example formed HVNW and HVPW regions 50 and 52). Moreover, it is contemplated for additional and/or other steps of the device fabrication workflow forming the electronic devices 12 to be interspersed between the previously described steps S1, S2, S3, S4, S5, and/or S6.

In the embodiment of FIG. 1, the semiconductor structure includes inner and outer DTI rings 30 and 32.

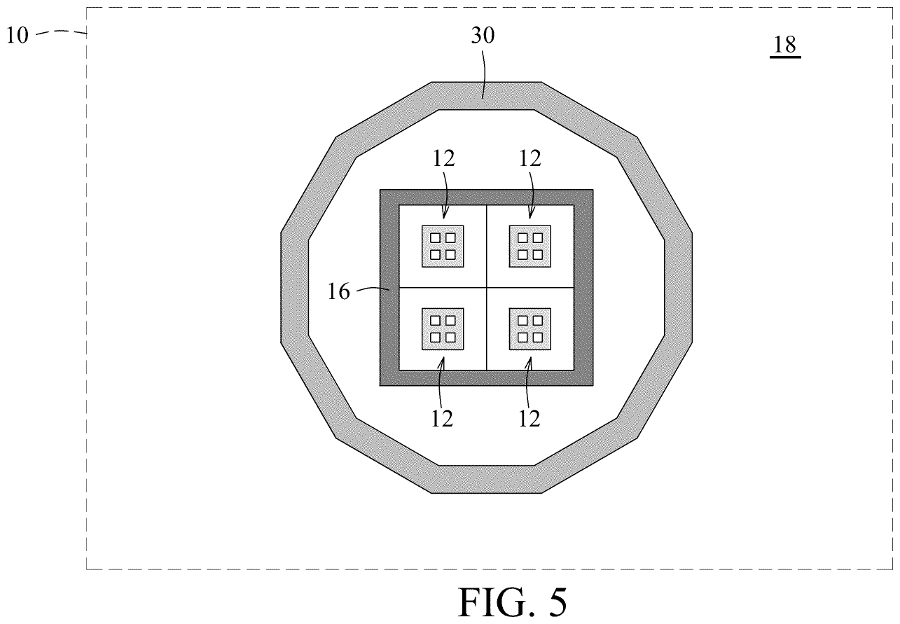

With reference now to FIG. 5, in a variant embodiment a semiconductor structure again includes the one or more (illustrative four) electronic devices 12 formed in a device area 16 of a semiconductor layer or substrate (i.e., like the semiconductor layer or substrate 10 of the embodiment of FIGS. 1 and 2) and surrounded by STI 18. However, unlike the embodiment of FIG. 1, the embodiment of FIG. 5 includes only a single DTI ring 30. The illustrative single DTI ring 30 has the same twelve-sided polygonal layout as the inner DTI ring 30 of the embodiment of FIG. 1. The embodiment of FIG. 5 advantageously can be designed to have a reduced total area.

The embodiment of FIG. 1 advantageously can provide improved EMI protection through the use of two DTI rings 30 and 32. Although not shown, it will be appreciated that further DTI rings (e.g., three DTI rings, or four DTI rings, or more) can provide still further improved EMI protection.

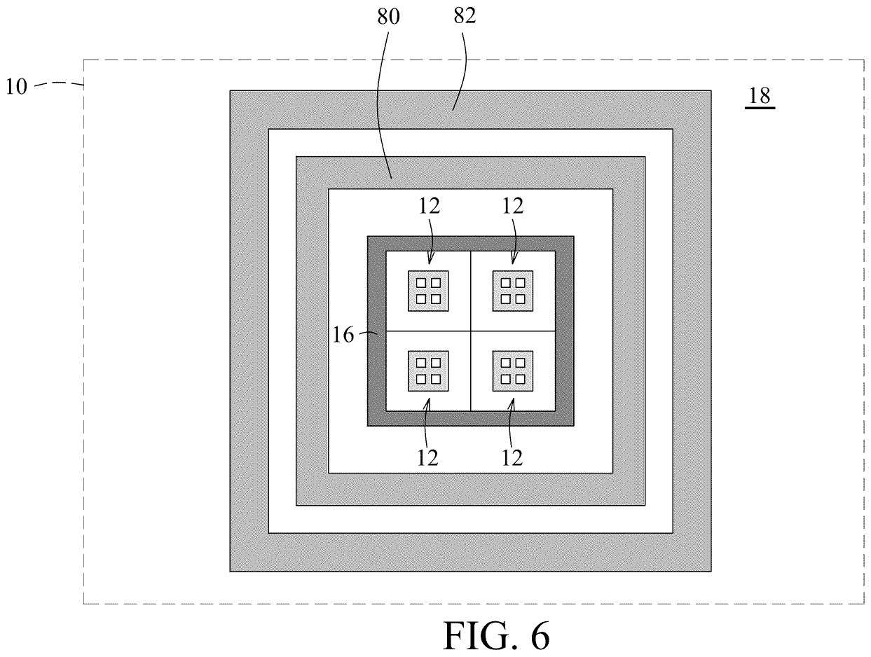

With reference now to FIG. 6, in another variant embodiment a semiconductor structure again includes the one or more (illustrative four) electronic devices 12 formed in a device area 16 of a semiconductor layer or substrate (i.e., like the semiconductor layer or substrate 10 of the embodiment of FIGS. 1 and 2) and surrounded by STI 18. However, unlike the embodiment of FIG. 1, the embodiment of FIG. 5 includes: an inner DTI ring 80 which corresponds to the inner DTI ring 30 of the embodiment of FIG. 1, but has a square (or, more generally, rectangular) layout with N=4; and, and outer DTI ring 82 which corresponds to the outer DTI ring 32 of the embodiment of FIG. 1, but has a square (or, more generally, rectangular) layout with N=4. The four-sided polygonal DTI rings 80 and 82 of FIG. 6 can advantageously simplify mask designs compared with masks for fabricating polygonal DTI rings with a higher number of sides, and the four sides may be more easily aligned with an underlying crystal structure of the semiconductor layer or substrate. A further advantage of the square or rectangular DTI rings 80 and 82 of the embodiment of FIG. 6 is that they can enable closer packing of devices. Furthermore, the inclusion of two square or rectangular DTI rings 80 and 82 advantageously provides enhanced EMI protection compared with having only a single square or rectangular DTI ring.

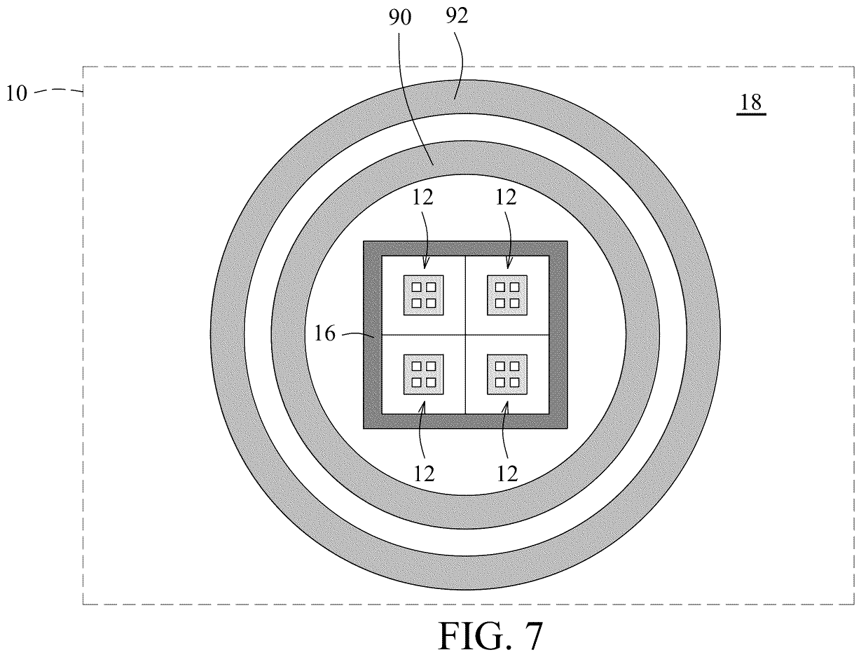

With reference now to FIG. 7, in another variant embodiment a semiconductor structure again includes the one or more (illustrative four) electronic devices 12 formed in a device area 16 of a semiconductor layer or substrate (i.e., like the semiconductor layer or substrate 10 of the embodiment of FIGS. 1 and 2) and surrounded by STI 18. However, unlike the embodiment of FIG. 1, the embodiment of FIG. 5 includes: a circular or oval inner DTI ring 90 which corresponds to the inner DTI ring 30 of the embodiment of FIG. 1; and a circular or oval outer DTI ring 92 which corresponds to the outer DTI ring 32 of the embodiment of FIG. 1. As previously mentioned, the circular or oval DTI rings 90 and 92 conceptually correspond to polygonal layouts with the number of sides N approaching infinity, i.e., N→∞). The circular or oval DTI rings 90 and 92 have no corners that could serve as initiation points for voltage breakdown. Hence, the circular or oval DTI rings 90 and 92 can advantageously provide EMI protection with enhanced (i.e., large) breakdown voltage (BV). Although FIG. 7 illustrates two circular or oval DTI rings 90 and 92, it is contemplated to have only a single circular or oval DTI ring (e.g., by omitting the outer circular or oval DTI ring 92); or, in other embodiments, to have three or more circular or oval DTI rings to provide further-enhanced EMI protection.

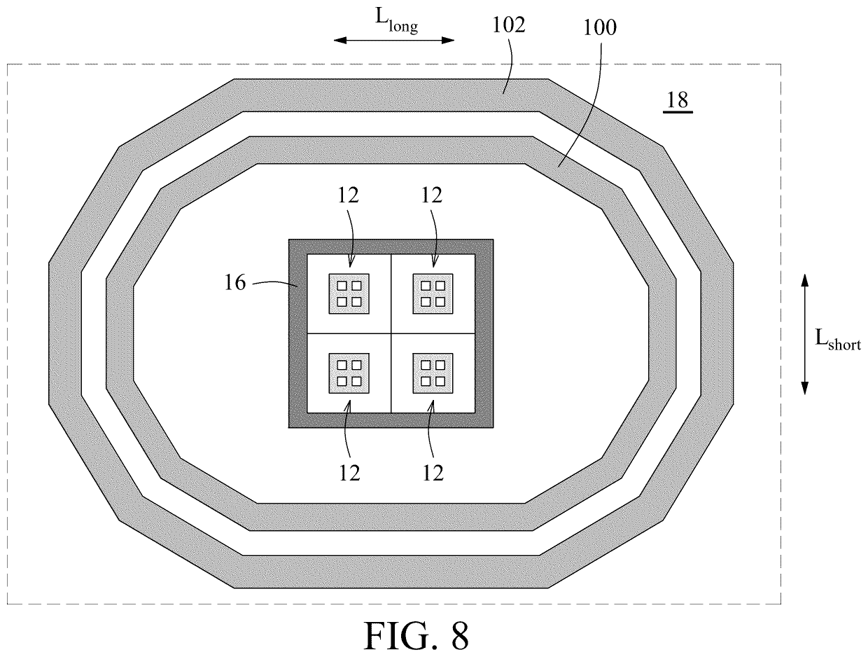

With reference now to FIG. 8, in another variant embodiment a semiconductor structure again includes the one or more (illustrative four) electronic devices 12 formed in a device area 16 of a semiconductor layer or substrate (i.e., like the semiconductor layer or substrate 10 of the embodiment of FIGS. 1 and 2) and surrounded by STI 18. The embodiment of FIG. 5 also includes an inner DTI ring 100 and an outer DTI ring 102 which correspond to the inner DTI ring 30 and outer DTI ring 32, respectively. The embodiment of FIG. 8 differs from that of FIG. 1 in that the DTI rings 100 and 102 have polygonal layouts with unequal sides: namely, two opposite sides of the DTI rings 100 and 102 have a longer length L_{long} that is longer than to other opposite sides of the DTI rings 100 and 102 which have shorter length Lₛₕₒᵣₜ, where L_{long}>Lₛₕₒᵣₜ. FIG. 8 illustrates that the geometries of the DTI rings may be chosen to fit a designated area. As another example, in the case of circular or oval DTI rings 90 and 92 as in the embodiment of FIG. 7, if these rings are oval (but not circular), then they have a longer dimension (i.e., the long axis of the oval) and a shorter dimension (i.e., the short axis of the oval).

In any of the embodiments of FIGS. 5, 6, 7, and 8, the DTI rings can have slanted or angled sidewalls at angle A_{DTI} as labeled in FIGS. 2 and 4D-4F, with the advantage of facilitating optional channel stop doping to form the optional channel stop implant 36 surrounding the filler material 34. Likewise, in any of the embodiments of FIGS. 5, 6, 7, and 8, the DTI rings can have rounded bottoms 74 as labeled in FIG. 4D.

In the following, some further embodiments are described.

In a nonlimiting illustrative embodiment, a method of fabricating a semiconductor structure includes: forming at least one deep trench isolation (DTI) ring encircling a device area, each DTI ring having a circular layout, an oval layout, or a polygonal layout with at least five sides; and forming at least one electronic device in the device area.

In a nonlimiting illustrative embodiment, a method of fabricating a semiconductor structure includes: etching at least one trench ring into a semiconductor layer or substrate with sidewalls that are not perpendicular respective to a surface of the semiconductor layer or substrate; performing ion implantation into the sidewalls and bottom of the at least one trench ring; filling the at least one trench ring with a filler material to form a corresponding at least one DTI ring; and forming at least one electronic device inside the at least one DTI ring.

In a nonlimiting illustrative embodiment, a semiconductor structure includes at least one electronic device, an inner DTI ring encircling the at least one electronic device, and an outer DTI ring encircling the inner DTI ring.

In some nonlimiting illustrative embodiments, at least one electronic device is encircled by an inner DTI ring and an outer DTI ring encircling the inner DTI ring. A semiconductor structure includes at least one electronic device surrounded by at least one DTI ring, where each DTI ring has a circular layout, an oval layout, or a polygonal layout with at least five sides. A method of fabricating a semiconductor structure includes etching at least one trench ring into a semiconductor layer or substrate with sidewalls that are not perpendicular respective to a surface of the semiconductor layer or substrate, performing ion implantation into the sidewalls and bottom of the at least one trench ring, filling the at least one trench ring with a filler material to form a corresponding at least one DTI ring, and forming at least one electronic device inside the at least one DTI ring.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor structure, the method comprising:
forming at least one deep trench isolation (DTI) ring encircling a device area, each DTI ring having a circular layout, an oval layout, or a polygonal layout with at least five sides; and
forming at least one electronic device in the device area.

2. The method of claim 1, wherein the forming includes forming at least two DTI rings encircling the device area.

3. The method of claim 1, wherein each DTI ring has polygonal layout with at least six sides.

4. The method of claim 1, wherein the forming includes:
etching a trench ring corresponding to each DTI ring;
performing ion implantation into a sidewall and bottom of each trench ring; and
filling each trench ring with a filler material to form the corresponding DTI ring.

5. The method of claim 4, wherein the filler material comprises polycrystalline silicon.

6. The method of claim 4, wherein the etching of the trench ring forms the trench ring with a rounded bottom.

7. The method of claim 4, wherein the etching of the trench ring forms the trench ring with sidewalls angled at between 85 degrees and 88 degrees.

8. The method of claim 1, wherein a depth of the at least one DTI ring is greater than or equal to a depth of the at least one electronic device.

9. The method of claim 1, further comprising:
prior to forming the at least one DTI ring, forming shallow trench isolation (STI) in a surrounding region that surrounds the device area;
wherein the at least one DTI ring is formed in the surrounding region.

10. A method of fabricating a semiconductor structure, the method comprising:
etching at least one trench ring into a semiconductor layer or substrate with sidewalls that are not perpendicular respective to a surface of the semiconductor layer or substrate;
performing ion implantation into the sidewalls and bottom of the at least one trench ring;
filling the at least one trench ring with a filler material to form a corresponding at least one deep trench isolation (DTI) ring; and
forming at least one electronic device inside the at least one DTI ring.

11. The method of claim 10, wherein the at least one trench ring has an oval or circular layout.

12. The method of claim 10, wherein the at least one trench ring has a polygonal layout with a largest angle between any two adjacent sides that is less than 90 degrees.

13. The method of claim 10, wherein the at least one DTI ring includes an outer DTI ring and an inner DTI ring disposed inside the outer DTI ring, and the at least one electronic device is formed inside the inner DTI ring.

14. The method of claim 10, wherein the filler material comprises polycrystalline silicon.

15. The method of claim 10, wherein each sidewall is angled at between 85 degrees and 88 degrees respective to the surface of the semiconductor layer or substrate.

16. The method of claim 10, further comprising:
prior to etching the at least one trench ring, forming shallow trench isolation (STI) surrounding a device area;
wherein the at least one trench ring is etched through the STI; and
wherein the at least one electronic device is formed in the device area.

17. A semiconductor structure comprising:
at least one electronic device;
an inner deep trench isolation (DTI) ring encircling the at least one electronic device; and
an outer DTI ring encircling the inner DTI ring.

18. The semiconductor structure of claim 17, wherein:
the inner DTI ring is polygonal with at least five sides; and
the outer DTI ring is polygonal with at least five sides.

19. The semiconductor structure of claim 17, further comprising:
shallow trench isolation (STI) surrounding the at least one device;
wherein the inner DTI ring passes through the STI; and
wherein the outer DTI ring passes through the STI.

20. The semiconductor structure of claim 17, further comprising:
an inner doped region conformally surrounding the inner DTI ring; and
an outer doped region conformally surrounding the outer DTI ring.
